(19) United States
(12) Patent Application Publication
(10) Pub. No.: US 2012/0141783 A1
(43) Pub. Date: Jun. 7, 2012

(54) ALUMINUM OXIDE COATED BODY AND METHOD FOR THE PRODUCTION THEREOF

(75) Inventors: Mandy Hoehn, Dresden (DE); Ingolf Endler, Coswig (DE)

(73) Assignee: FRAUNHOFER-GESELLSCHAFT ZUR FOERDERUNG DER ANGEWANDTEN FORSCHUNG E.V., Muenchen (DE)

(21) Appl. No.: 13/389,069

(22) PCT Filed: Aug. 10, 2010
(86) PCT No.: PCT/EP2010/061605

§ 371 Date: Feb. 6, 2012

(30) Foreign Application Priority Data
Aug. 17, 2009 (DE) 10 2009 028 577.6

(51) Int. Cl. B32B 9/04; C23C 16/40; B32B 5/00; B32B 15/04; B32B 18/00

(52) U.S. Cl. 428/335; 428/469; 428/446; 428/702; 428/698; 428/697; 427/255.31

(57) ABSTRACT

The invention relates to bodies made of metal, hard metal, cermet, ceramic or semiconductor material, which are coated with an Al₂O₃-layer or a multi-layered layer system containing at least one Al₂O₃-layer, and to a method for coating the type of bodies. The aim of the invention is to coat bodies made of metal, cermet, ceramic or semiconductor material with one or more Al₂O₃-layers, the layers being very hard >27 GPa and having an improved resistance to wear compared to traditional Al₂O₃-layers and are economical to produce. In the claimed coated bodies, the Al₂O₃-layer comprises totally or mainly a phase mixture of θ (theta)-aluminum oxide and γ (gamma)-aluminum oxide. In order to produce this type of coated body, the invention proposes a method in which the bodies are coated at temperatures of between 700° C. and 1050° C. and pressures >0.2 kPa by means of a thermal CVD-process without plasma stimulation, and one or more aluminum halogenides are used as oxygen precursor N₂O and as Al-precursors. The claimed layer can be used as a wear-resistant layer, for example for coating Si₃N₄- and WC/Co indexable inserts. The layer can also be applied as an electrically insulating layer to various components such as, electrical leadthroughs.

### TECHNICAL FIELD

The invention relates to bodies of metal, hard metal, cermet, ceramic or semiconductor material, which are coated with an Al₂O₃ layer or a multi-layered coating system that contains at least one Al₂O₃ layer, and to methods for the coating of such bodies. The inventive layer is eminently suitable as an anti-wearing layer, for example for the coating of Si₃N₄ and WC/Co indexable inserts. However, the layer may also be applied as an electrically insulating layer on various structural elements, such as, for example, electrical penetrations.

### STATE OF THE ART

Aluminum oxide (Al₂O₃) exists not only as the thermodynamically stable α-Al₂O₃ phase but ,also as a series of metastable polymorphs, such as, for example, κ-, θ-, γ-, δ-, η- and χ-Al₂O₃.

For the production of aluminum oxide layers, chemical vapor-phase deposition (CVD) and physical vapor-phase deposition (PVD) among other techniques are used. In this connection, the occurrence of the α-, κ-, θ- or γ-Al₂O₃ phases is reported, depending on the process conditions.

In the case of the thermal CVD process, which is widely used industrially and which works conventionally with CO₂ as an oxygen precursor, the κ-Al₂O₃ phase predominates in addition to the stable α-Al₂O₃ phase. Both modifications can be deposited in controlled manner by modern CVD technology, as shown, for example, in U.S. Pat. Nos. 5,137,774 and 5,700,569. Furthermore, according to EP 1 122 334 B1, the production of pure γ-Al₂O₃ layers by use of H₂S dopant and selective temperature control of the thermal CVD process is also known. If the plasma-assisted CVD (PACVD) or PVD variants are used as the coating process for the production of Al₂O₃ layers, as described in the patents EP 1 034 319 B1 and EP 1 253 215 B1, γ- or α-Al₂O₃ layers as well as mixtures of the two modifications are formed. The same is also true for the Al₂O₃ layers described in the literature that were produced by means of metalloorganic CVD (MOCVD) (see S. Blittersdorf, N. Bahlawane, K. Kohse-Höinghaus, B. Atakan, J. Müller, Chem. Vap. Deposition 9 (2003) 194-198).

If the layers consisting of various aluminum oxide modifications are compared with one another, it is found that the thermodynamically stable α-Al₂O₃ phase produced by means of thermal CVD at temperatures >1000° C. has the highest hardness of around 27 GPa. The κ-Al₂O₃ layer produced by means of thermal CVD has a somewhat lower hardness with values of around 25 GPa. High hardness values and good wearing properties are also reported for γ-Al₂O₃ produced by means of PVD or plasma-assisted CVD (see WO 99/24634 and U.S. Pat. No. 5,879,823). For the γ-Al₂O₃ layers produced by means of thermal CVD according to EP 1 122 334 B1, a high hardness of around 27 GPa is also reported. According Larsson and Ruppi (A. Larsson, S. Ruppi; Int. J. Refr. Metals & Hard Materials 19 (2001) 515-522), however, these layers exhibit, in the wear test, insufficient adhesion, which may possibly be attributed to too much inclusion of sulfur in the layer. Nevertheless, a high concentration of the H₂S dopant is a prerequisite for the achievement of the γ-Al₂O₃ modification by means of thermal CVD.

The θ-Al₂O₃ modification seldom occurs in CVD and PVC) layers, and then only as a small proportion in phase mixtures with α-Al₂O₃ (see I. Nasution, A. Velasco, H. Kim; J. of Crystal Growth 311 (2009) 429-434). As investigations of Chatfield, Lindström and Sjöstrand (C. Chatfield, J. N. Lindström, M. E. Sjöstrand, J. Phys. C5 (5) (1989) 377-387) show, the θ-Al₂O₃ modification in phase mixture with α-Al₂O₃ is then formed mainly at interfaces with the substrate.

According to the state of the art, exclusively the precursor system AlCl₃-CO₂-H₂ is used for the industrial deposition of aluminum oxide layers by means of CVD. This system offers the possibility of producing aluminum oxide modifications selectively by addition of dopants such as H₂S and by selection of the CVD temperature window. The formation of water necessary for the formation of aluminum oxide takes place in situ from CO₂ and H₂. However, this process yields the reactant H₂O in sufficient quantities only at temperatures above 900° C., from which the high CVD temperatures result.

The use of N₂O as the oxygen precursor instead of the conventionally used CO₂ is also known from some literature sources (B. Aspar, B. Armas, C. Combescure, D. Thenegal; J. de Phys. IV 1991, 1 (Coll.C2), 665-670 and C. Labatut, C. Combescure, B. Armas; J. de Phys. II 1993, 3 (Coll.C3), 589-596). The layers produced in this way consist of a mixture of α- and θ-Al₂O₃ at a deposition temperature of 1000° C. and exclusively of the stable α-Al₂O₃ phase at higher deposition temperatures. A disadvantage for industrial production is the very low deposition pressure of only 133 Pa in this process.

Heretofore it has been assumed that γ-Al₂O₃ can be obtained only by the low-temperature coating processes of PACVD, MOCVD and PVD as well as, in the case of thermal CVD, by addition of higher dopant concentrations of H₂S.

### EXPLANATION OF THE INVENTION

The task of the invention is to coat bodies of metal, cermet, ceramic or semiconductor material with one or more Al₂O₃ layers, which are characterized by a high hardness >27 GPa and a better wear resistance in comparison with conventional Al₂O₃ layers and which can be produced inexpensively.

This task is accomplished with the features of the patent claims, wherein the invention also includes even combinations of the individual independent claims within the meaning of an AND operator.

The inventively coated bodies are characterized in that the Al₂O₃ layer consists completely or predominantly of a phase mixture of θ (theta) aluminum oxide and γ (gamma) aluminum oxide.

If the Al₂O₃ layer does not consist completely of the phase mixture of θ (theta) aluminum oxide and γ (gamma) aluminum oxide, the layer may also contain, according to the invention, α (alpha)-Al₂O₃ or κ (kappa)-Al₂O₃.

According to an expedient configuration of the invention, the Al₂O₃ layer contains 5 to 30% by mass of θ aluminum oxide.

The inventive Al₂O₃ layer may also have a gradient with respect to the θ aluminum oxide content.

In the case of a multi-layered coating system of several Al₂O₃ layers with the phase mixture of θ aluminum oxide and γ aluminum oxide, the individual Al₂O₃ layers may, according to the invention, have different mass ratios of θ aluminum oxide to γ aluminum oxide.

Multi-layered coating systems of one or more Al₂O₃ layers with the phase mixture of θ aluminum oxide and γ aluminum oxide may, according to the invention, contain one or more further layers. The additional layers may be chosen from the group of materials α (alpha) Al₂O₃, γ-Al₂O₃, κ (kappa)-Al₂O₃, TiN, TiCN, TiC, TiAlN, TiAlCN, SiC and Si₃N₄.

The inventive Al₂O₃ layers with the phase mixture of θ aluminum oxide and γ aluminum oxide are characterized in that they have a fine crystalline structure with a crystallite size <200 nm. Layer thicknesses between 0.1 μm and 30 μm are advantageous.

By virtue of the fine crystalline structure, the inventive Al₂O₃ layer has small roughness and thus permits a high surface quality in chip-removing machining. Because of the fine-grained surface morphology, the post-treatment otherwise necessary according to the state of the art, meaning subsequent smoothing of the coarse crystalline aluminum oxide layers, can be dispensed with. The grain size of the inventive Al₂O₃ layer in the nanometer range additionally permits a higher coating quality of tools or bodies with sharp edges. Multi-layered structures permit a higher crack resistance under mechanical load. The inventive layer, which consists completely or predominantly of the nanocrystalline phase mixture of γ- and θ-Al₂O₃, has a surprisingly high hardness of up to 28 GPa. Higher hardnesses for Al₂O₃ have not been known heretofore. Because of the high electrical resistance, the layer also has a high application potential for components with thin insulating layers, such as, for example, penetrations.

For the production of bodies coated in this way, the invention includes a process in which the bodies are coated by means of a thermal CVD process without plasma excitation at temperatures between 700° C. and 1050° C. and pressures >0.2 kPa, wherein N₂O is used as oxygen precursor and one or more aluminum halides are used as Al precursor.

The CVD process is advantageously carried out at temperatures between 850° C. and 1050° C. and pressures between 0.5 kPa and 2.0 kPa.

The inventive process surprisingly permits the production of novel metastable phase mixtures, consisting of θ- and γ-Al₂O₃, by means of thermal CVD. Codeposition of these phases has been made possible by use of a precursor system, which uses N₂O as the oxygen precursor instead of the conventionally used CO₂. It has been found to be advantageous that fine-grained layers can be produced with high deposition rates at deposition temperatures as low as 850° C. Higher deposition rates than according to the state of the art are achieved with this layer system, especially in the industrially interesting medium temperature range of 850° C. to 950° C. These lower deposition temperatures also permit the coating of more temperature-sensitive substrates.

### EXAMPLES FOR EXECUTION OF THE INVENTION

The invention will be explained in more detail in the following by means of exemplary embodiments and the associated figures. The figures show:

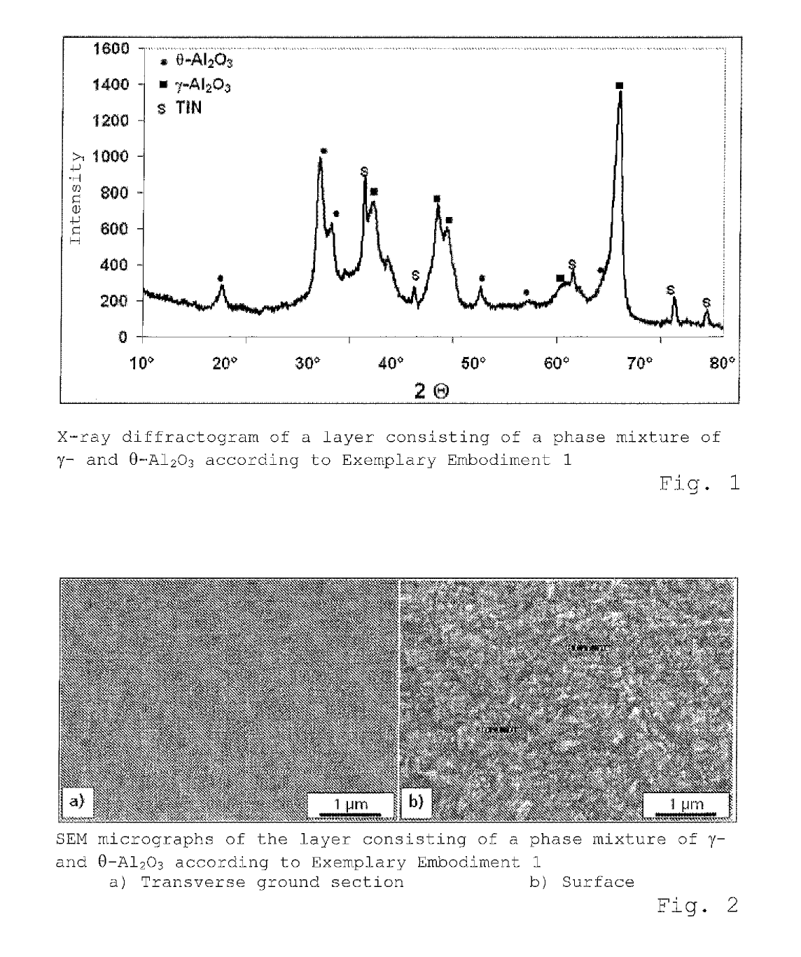

FIG. 1: the x-ray diffractogram of a layer consisting of a phase mixture of γ- and θ-Al₂O₃ (for Example 1),

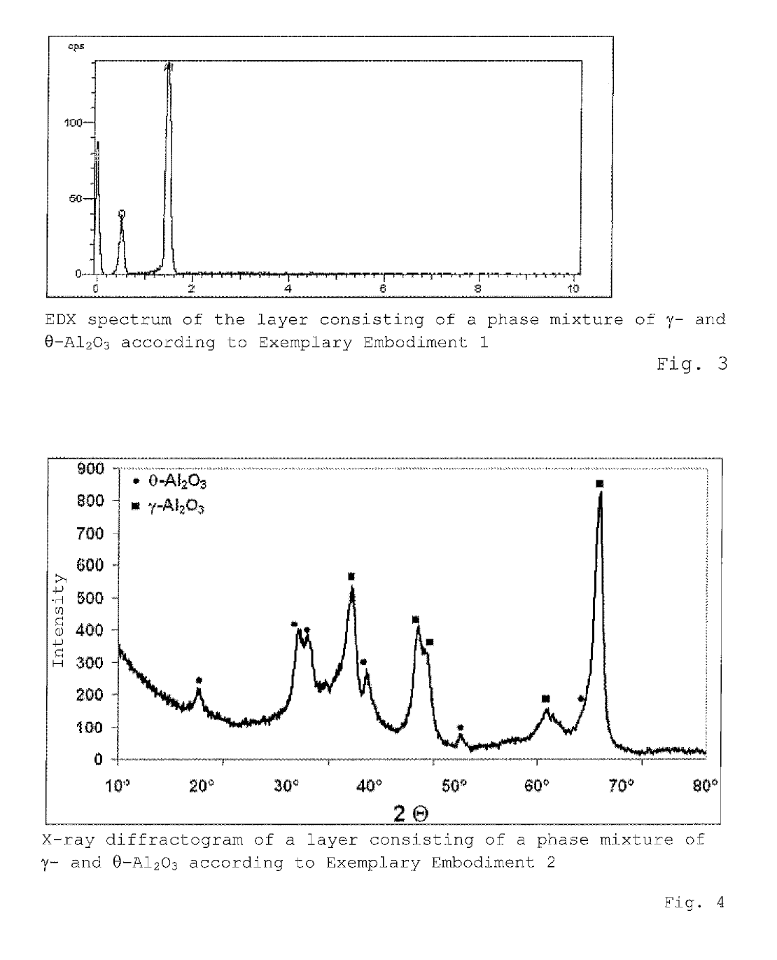

FIG. 2: SEM micrographs of the layer according to FIG. 1, wherein Fig. a) shows the transverse ground section and Fig. b) shows the surface,

FIG. 3: the EDX spectrum of the layer according to FIG. 1,

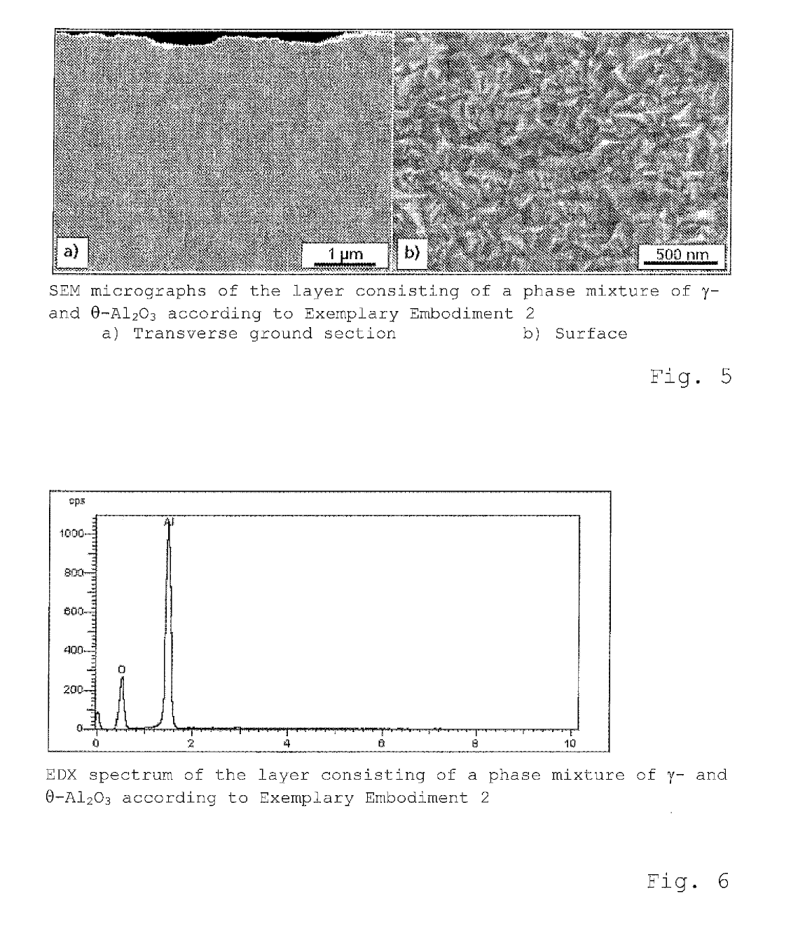

FIG. 4: the x-ray diffractogram of a further layer consisting of a phase mixture of γ- and θ-Al₂O₃ (for Example 2),

FIG. 5: SEM micrographs of the layer according to FIG. 4, wherein Fig. a) shows the transverse ground section and Fig. b) shows the surface,

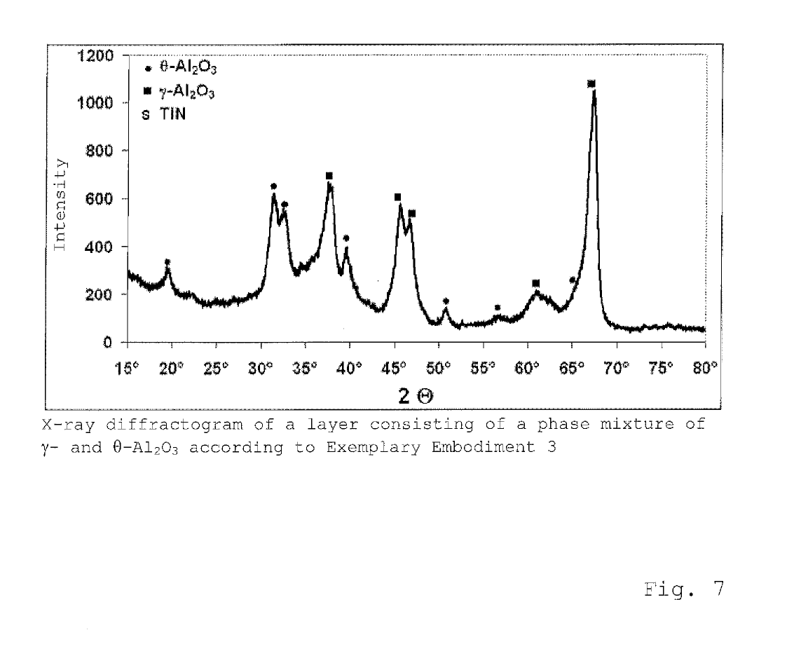

FIG. 6: the EDX spectrum of the layer according to FIG. 4,

FIG. 7: the x-ray diffractogram of a layer consisting of a phase mixture of γ- and θ-Al₂O₃ (for Example 3).

### EXAMPLE 1

Firstly a 1 μm thick TiN bonding layer and then the inventive layer is applied by means of a CVD process on Si₃N₄ ceramic indexable inserts.

The coating process is carried out in a hot-wall CVD reactor with an inside diameter of 75 mm. A gas mixture consisting of 66% by volume H₂, 3.0% by volume N₂O, 1.5% by volume AlCl₃, 1.5% by volume H₂S, 12% by volume N₂ and 16.5% by volume Ar is used at a temperature of 1030° C. and a pressure of 0.5 kPa. After a coating time of 180 minutes, a 4.5 μm thick layer is obtained.

This layer was investigated by means of x-ray thin-film analysis at grazing incidence (see x-ray diffractogram in FIG. 1). The diffractogram shows a phase mixture consisting of γ- and θ-Al₂O₃. In the transverse ground section of the sample (see FIG. 2a), the fine-grained, homogeneous structure of this layer is evident. The measurement of the aluminum oxide crystallite size on the surface and in the transverse ground section of the layers (see FIG. 2b) yields a crystallite size of 30-80 nm.

The determination of the chemical composition by means of EDX (see FIG. 3) shows that the layer consists of pure aluminum oxide.

Microhardness measurements with a Vickers indenter yielded a high hardness of 26.7±0.6 GPa.

The inventive layer consists of a phase mixture of γ- and θ-Al₂O₃. It is characterized by a smooth, homogeneous surface, by a fine-grained structure with a crystallite size smaller than 60 nm, and by the high hardness.

### EXAMPLE 2

The inventive layer is applied by means of a CVD process on WC/Co hard metal indexable inserts with a precoating consisting of 1 μm TiN and 2 μm TiCN.

The coating process is carried out in a hot-wall CVD reactor with an inside diameter of 75 mm. With the use of a gas mixture consisting of 66% by volume H₂, 2.5% by volume N₂O, 2.5% by volume AlCl₃, 12% by volume N₂ and 17% by volume Ar, a layer of γ- and θ-Al₂O₃ is obtained with a deposition rate of 0.9 μm/h at a temperature of 920° C. and a pressure of 1 kPa.

The composition of the layer was investigated by means of x-ray thin-film analysis at grazing incidence (see x-ray diffractogram in FIG. 4). The diffractogram shows a phase mixture of γ- and θ-Al₂O₃.

In the transverse ground section of the sample (see FIG. 4a), the fine-grained layer structure is evident. The determination of the aluminum oxide crystallite size by measurement on the surface and in the transverse ground section of the layers (see FIG. 4b) yields a crystallite size of 50 to 200 nm.

The chemical composition was determined by means of EDX (see FIG. 5). The layer consists of pure aluminum oxide.

Microhardness measurements with a Vickers indenter yielded a high hardness of 27.8±0.7 GPa.

The inventive layer consists of a phase mixture of γ- and θ-Al₂O₃ and is characterized by a smooth, homogeneous surface, by a fine-grained structure with a crystallite size smaller than 200 nm and by the high hardness.

### EXAMPLE 3

The inventive layer is applied by means of a CVD process as an insulating layer for electrical penetrations on a bar of steel 1.4541 with a 1 μm thick TiN precoating.

The coating process is carried out in a hot-wall CVD reactor with an inside diameter of 75 mm. A gas mixture consisting of 66% by volume H₂, 3.0% by volume N₂O, 1.5% by volume AlCl₃, 13.5% by volume N₂ and 16.5% by volume Ar is used at a temperature of 850° C. and a pressure of 0.5 kPa. After a coating time of 10 h, a 10 μm thick layer is obtained.

The composition of the layer was determined by means of x-ray thin-film analysis at grazing incidence (see x-ray diffractogram in FIG. 7). The diffractogram shows a phase mixture of γ- and θ-Al₂O₃.

The measurement of the specific electrical resistance yielded a value >10¹⁴ Ωcm.

The inventive layer consists of a phase mixture of γ- and θ-Al₂O₃. It is electrically insulating and is characterized by a high specific resistance, by a smooth, homogeneous surface and by a fine-grained structure with a crystallite size smaller than 150 nm.

1. Coated bodies of metal, hard metal, cermet, ceramic or semiconductor material, coated with an Al₂O₃ layer or with a multi-layered coating system that contains at least one Al₂O₃ layer, wherein the Al₂O₃ layer consists completely or predominantly of a phase mixture of θ (theta) aluminum oxide and γ (gamma) aluminum oxide.

2. Coated bodies according to claim 1, wherein the Al₂O₃ layer consists predominantly of the phase mixture of θ aluminum oxide and γ aluminum oxide and additionally contains α (alpha)-Al₂O₃ or κ (kappa)-Al₂O₃.

3. Coated bodies according to claim 1, wherein the Al₂O₃ layer contains 5 to 30% by mass of θ aluminum oxide.

4. Coated bodies according to claim 1, wherein the Al₂O₃ layer has a gradient with respect to the θ aluminum oxide content.

5. Coated bodies according to claim 1, wherein the multi-layered coating system consists of several Al₂O₃ layers with the phase mixture of θ aluminum oxide and γ aluminum oxide, wherein the individual Al₂O₃ layers have different mass ratios of θ aluminum oxide to γ aluminum oxide.

6. Coated bodies according to claim 1, wherein the multi-layered coating system consists of one or more Al₂O₃ layers with the phase mixture of θ aluminum oxide and γ aluminum oxide as well as of one or more further layers, chosen from the group of materials α-Al₂O₃, γ-Al₂O₃, κ-Al₂O₃, TiN, TiCN, TiC, TiAlN, TiAlCN, SiC and Si₃N₄.

7. Coated bodies according to claim 1, wherein the Al₂O₃ layer with the phase mixture of θ aluminum oxide and γ aluminum oxide has a fine crystalline structure with a crystallite size <200 nm.

8. Coated bodies according to claim 1, wherein the inventive Al₂O₃ layer with the phase mixture of θ aluminum oxide and γ aluminum oxide has a layer thickness between 0.1 μm and 30 μm.

9. Method for the coating of bodies of metal, hard metal, cermet, ceramic or semiconductor material with an Al₂O₃ layer or with a multi-layered coating system that contains at least one Al₂O₃ layer, which consists completely or predominantly of a phase mixture of θ aluminum oxide and γ aluminum oxide, by the fact that the bodies are coated by means of a thermal CVD process without plasma excitation at temperatures between 700° C. and 1050° C. and pressures >0.2 kPa, wherein N₂O is used as oxygen precursor and one or more aluminum halides are used as Al precursor.

10. Method according to claim 9, wherein the CVD process is carried out at temperatures between 850° C. and 1050° C.

11. Method according to claim 9, wherein the CVD process is carried out at pressures between 0.5 kPa and 2.0 kPa.
